(19) United States
(12) Patent Application Publication
(10) Pub. No.: US 2006/0124448 A1
(43) Pub. Date: Jun. 15, 2006

(54) Thin film semi-permeable membranes for gas sensor and catalytic applications

(76) Inventors: RaviPrakash Jayaraman, State College, PA (US); Mark W. Horn, Port Matilda, PA (US); Lawrence J. Pilione, State College, PA (US); Russell F. Messier, State College, PA (US); Anthony H. McDaniel, Livermore, CA (US)

Correspondence Address: GIFFORD, KRASS, GROH, SPRINKLE & CITKOWSKI, P.C, PO BOX 7021, TROY, MI, 48007-7021, US

(21) Appl. No.: 10/543,348

(22) PCT Filed: Jan. 23, 2004
(86) PCT No.: PCT/US04/01838

§ 371 Date: Jan. 23, 2006

Related U.S. Application Data
(60) Provisional application No. 60/442,397, filed on Jan. 23, 2003.

(51) Int. Cl. C23C 14/00; G01N 27/26

(52) U.S. Cl. 204/192.15; 204/431

(57) ABSTRACT

The invention relates to novel sensors of the catalytic gas-sensing thin-film metal surface type wherein the surface has an inorganic protective membrane coating formed by a pulsed dc sputtering technique. Preferably, the thin-film metal surface is a Pd, Pt, Ni, Au, Ag or an alloy thereof. The inorganic membrane is of the formula MaObNcCd where M is a metal or semiconductor, O is oxygen, N is nitrogen, and C is carbon and a, b, c, and d can each independently range from zero to seven with the proviso that at least two of a, b, c, and d are non-zero. The sensor design is particularly useful for various hydrogen sensing applications. The invention also includes their method of manufacture.

### REFERENCE TO RELATED APPLICATION

This application claims priority to provisional application U.S. Ser. No. 60/442,397, filed Jan. 23, 2003, the entire content of which is incorporated herein by reference.

### GRANT REFERENCE

The research carried out in connection with this invention was supported by The United States Department of Energy Grant No. DE-FC07-OOCH11031. Accordingly, the United States Government may have certain rights in this invention.

### FIELD OF THE INVENTION

The present invention relates to a hydrogen sensor and process for manufacture thereof. More specifically, the present invention relates to a hydrogen sensor including a hydrogen permeable protective layer and processes for making the sensor.

### BACKGROUND OF THE INVENTION

Hydrogen has long been viewed as the fuel of the future since it is abundant and is relatively non-toxic. Hydrogen is a particularly attractive fuel because of its clean burning properties.

A number of industries currently use hydrogen in manufacturing processes and/or as a fuel. For example:
Chemical industry—hydrogen is used in refining crude oil, creating a reducing environment in the float glass industry
Food industry—hydrogen is used for hydrogenation of oils and fats
Semiconductor industry—hydrogen is used as a processing gas in thin film deposition and in annealing atmospheres
Transportation industry—hydrogen is used in fuel cells

However, the perception of hydrogen as dangerously explosive and difficult to store and handle continues to inhibit development of this potentially valuable resource. In particular, although hydrogen actually has a higher self-ignition temperature than gasoline, it is flammable in concentrations as low as 4 percent by volume. Thus, it is important to detect even a small leak as quickly as possible.

In addition to the importance of detecting hydrogen for safety reasons, accurate and real-time estimation of hydrogen is highly desirable in industry where control of hydrogen concentration is of economic and quality-control significance. For example, in the process of refining crude oil, the exhaust of the refining process contains hydrogen which is recycled and fed back to the process stream. It would be of great economic benefit to the processor to have a good estimate of the hydrogen content in the exhaust so that the process can be accurately regulated.

There are a number of hydrogen sensing technologies currently available, including mass spectroscopy, gas chromatography and thin film sensors. Of these, thin film hydrogen sensors have the advantages of being relatively more compact and faster in detection than the other methods. However, thin film hydrogen sensors are vulnerable to “poisoning” by some substances, such as carbon monoxide, oxygen, sulfur dioxide, and hydrogen sulfide. These and other gases interfere with hydrogen adsorption on the surface of the thin film sensor. As a result, the function of thin film hydrogen sensors is often compromised in a mixed gas environment.

Thus, there is a continuing need for a hydrogen sensor that is chemically selective, that is, a sensor which efficiently detects hydrogen even in a mixed gas environment.

### SUMMARY OF THE INVENTION

Provided is a hydrogen sensor according to the present invention that includes a metal film capable of altering at least one of its physical parameters when exposed to hydrogen; and a hydrogen permeable inorganic layer deposited on the metal film. The inorganic layer is deposited by a physical vapor deposition process, particularly by sputter deposition and preferably by magnetron sputtering deposition, including magnetron sputtering using a direct current power source. Optionally, the direct current power source is a pulsed direct current power source.

In a preferred embodiment of a provided sensor, the metal film includes a catalytic metal, particularly palladium and optionally further including nickel. Where the optional nickel is included it is present in amounts ranging between 0.1-20% of the total weight of the metal film.

A hydrogen permeable inorganic layer included in a sensor according to the invention includes a compound selected from the group consisting of: a metal oxide, a metal nitride, a metal carbide, a metal oxynitride, a semiconductor oxide, a semiconductor nitride, a semiconductor carbide, a semiconductor oxynitride, and combinations thereof. A preferred embodiment includes an oxide of silicon in the hydrogen permeable inorganic layer. Optionally, the oxide of silicon is silicon dioxide. A hydrogen permeable inorganic layer ranges between 10-1000 Angstroms in thickness, optionally ranging between 50-400 Angstroms in thickness.

Also provided is a process for producing a hydrogen permeable layer on a substrate wherein the layer includes an oxide of a metal or semiconductor. The process includes the steps of providing a target including a carbide of the metal or semiconductor; bombarding the target with ions from a reactive plasma sputtering source such that an oxide of the metal or semiconductor is produced; and positioning a substrate such that the oxide of the metal or semiconductor is deposited on the substrate, thereby producing the layer including the oxide of a metal or semiconductor on the substrate.

An optional step included in an inventive process is a step of producing a substrate wherein the substrate is preferably a thin metal film including a catalytic metal. Optionally, the catalytic metal is selected from the group consisting of: Pd, Pt, Ni, Au, Ag and an alloy thereof. In a further option, the thin metal film is deposited on a support by a sputtering process. The semiconductor may be silicon and the target may include silicon carbide. The sputtering source is optionally a direct current magnetron sputtering source and further optionally a direct current magnetron sputtering source is a pulsed direct current magnetron sputtering source.

Further provided by the present invention is a hydrogen sensor including a thin film containing palladium, the film capable of altering at least one of its physical parameters when exposed to hydrogen; and a hydrogen permeable layer including an oxide of silicon deposited on the thin film, wherein the hydrogen permeable layer is deposited by a pulsed direct current magnetron sputtering deposition process. Optionally, the thin film further includes nickel. Further options include the provision that the pulsed direct current magnetron sputtering deposition process for deposition of the hydrogen permeable layer includes the step of providing a target, the target including silicon carbide. In an additional option, a thin film is deposited by a direct current magnetron sputtering deposition process.

Also provided is a hydrogen sensor including a metal film containing palladium, the film capable of altering at least one of its physical parameters when exposed to hydrogen; and a hydrogen permeable inorganic layer including silicon dioxide deposited on the metal film. In this embodiment, the hydrogen permeable inorganic layer is deposited by a method including a pulsed direct current magnetron sputtering deposition process and the hydrogen permeable inorganic layer ranges between 10-1000 Angstroms in thickness. Optionally, the metal film further comprises nickel and further optionally the nickel is present in an amount in the range between 0.1-20% of the total weight of the metal film. The thin film may be formed by a direct current magnetron sputtering deposition process.

### BRIEF DESCRIPTION OF THE DRAWING

FIG. 1 is a schematic depiction of a sputtering system which may be employed in the practice of the present invention.

### DETAILED DESCRIPTION OF THE INVENTION

Hydrogen Sensor

A hydrogen sensor according to the present invention includes a thin film layer which is capable of altering at least one of its physical parameters when exposed to hydrogen. An inventive hydrogen sensor further includes a hydrogen permeable layer deposited on the thin film. The hydrogen permeable layer is preferably deposited on the thin film by a physical vapor deposition process.

Thin Film Layer

An inventive hydrogen sensor includes a thin film layer which is capable of altering at least one of its physical parameters when exposed to hydrogen. In a preferred embodiment a thin film layer is a metal thin film layer. A thin film metal layer includes a metal, such as a transition metal. Preferred transition metals included in an thin film metal layer are catalytic metals illustratively including Pd, Pt, Ni, Au, Ag and alloys thereof. A thin film layer may include rare earth metals and alloys thereof, an alloy of a transition metal and a rare earth metal or alkaline earth metal, and other hydrogen adsorbing and absorbing materials such as metal hydrides disclosed in U.S. Pat. No. 6,539,774.

As noted above, a thin film layer included in an inventive sensor may be an alloy. A preferred alloy is a palladium/nickel alloy where nickel is included in the range of 1-50 atomic %, preferably 6 to 25 atomic %. The composition of an alloy included in a film may affect hydrogen adsorption and/or absorption properties of the film. For example, alloy films, including palladium and nickel alloy films, can detect larger concentrations of hydrogen without undergoing the α→β phase transition which can cause mechanical instability in a thin film metal layer. A Pd/Ni alloy may inhibit phase change for hydrogen concentrations in the range of 0 to 100%. For further details see Thomas R. C. and Hughes R. C. “Sensors for Detecting Molecular Hydrogen Based on Pd Metal Alloys”. J. Electrochemical Society, 144(9):3245-3249, 1997; Hughes R. C. and Schubert W. K. “Thin Films of Pd/Ni Alloys for Detection of High Hydrogen Concentrations”. J. Applied Physics, 71(1):542-544,1992; Hughes R. C., Schubert W. C. and Buss R. J. “Solid-State Hydrogen Sensors Using Pd—Ni Alloys: Effect of Alloy Composition on Sensor Response”. J. Electrochemical Society, 142(1):249-254, 1995.

Further examples of palladium alloys incorporated in an inventive sensor include alloys of palladium/iron, palladium/silver, palladium/copper, palladium/chromium, palladium/boron and palladium/gold.

The interaction of hydrogen with the thin film layer of a hydrogen sensor results in measurable changes in the physical parameters, such as mechanical, electrical or optical properties, of the thin film layer. Such changes are detected and/or quantitated in order to detect and/or quantitate hydrogen in a sample or in the environment of a sensor containing the thin film metal. Depending on the physical parameter to be detected or measured in order to detect or measure hydrogen, a thin film layer is included in any of various hydrogen sensor configurations. For example, a thin film layer may be coated on an optical fiber where detection of changes in optical properties are a desirable readout of hydrogen presence or concentration. Adsorption of hydrogen on the thin film layer in an optical detector alters an optical property of the fiber, allowing detection and/or quantitation of hydrogen in a sample. Further examples of hydrogen sensor configurations include metal oxide semiconductor devices such as capacitors and field effect transistors wherein the hydrogen adsorbed on the thin film layer forms a dipole at the metal oxide interface causing a detectable and measurable change in the electrical characteristics of the device; chemiresistor devices in which a change in resistivity of a thin film layer in the presence of hydrogen is monitored to detect and/or estimate the hydrogen content in the environment or sample. Another type of hydrogen sensor is a pyroelectric sensor in which a thin film layer is deposited on the surface of a pyroelectric material. A pyroelectric material is one in which polarization is a function of temperature. Hence, variation in temperature causes a potential difference between opposing surfaces in this material. Heat created by the adsorption of hydrogen on the thin film layer produces a potential difference that is used to detect/estimate hydrogen in a sample. Additional hydrogen sensor configurations include a piezoelectric sensor in which adsorption of hydrogen on a piezoelectric material that has a thin film coating alters the oscillation frequency of the piezoelectric material and coating, enabling hydrogen detection and/or quantitate; and a surface acoustic wave sensor in which a perturbation of surface acoustic wave on a piezoelectric substrate coated with a thin film layer is measured.

In general, a thin film layer included in an inventive sensor is less than one millimeter in thickness. Preferably, thickness of a thin film layer ranges between 10-5000 nanometers. More preferably, thin film layer thickness ranges between 20-500 nanometers. Still more preferably, thickness of a thin film layer ranges between 30-300 nanometers.

A thin film layer included in an inventive sensor is manufactured by any of various methods. For example, a thin film layer may be formed by techniques illustratively including physical vapor deposition techniques such as vacuum evaporation, sputtering, arc vapor deposition, thermal evaporation, sputtering, pulsed laser deposition techniques and ion-beam-assisted deposition; chemical vapor deposition; solution deposition; and combinations thereof. Thin film layer formation techniques are known in the art and specifics of such techniques are detailed in general references such as Park, J-H, Chemical Vapor Deposition, ASM Intl, 2001; Mahan, J., Physical Vapor Deposition of Thin Films, Wiley-Interscience, 2000; and Maftox, D. M., Handbook of Physical Vapor Deposition (PVD) Processing, Noyes Publications, 1998; as well as herein.

In one embodiment of an inventive sensor, a thin film layer is formed by sputtering. More particularly, a palladium or palladium/nickel alloy is formed by sputtering, preferably by a method of magnetron sputtering using a palladium or palladium/nickel target, or co-sputtering from a palladium target and nickel target simultaneously, depending on the desired composition of the thin film layer. A further preferred sputtering method employs a direct current sputtering source, and/or a pulsed direct current source. Sputtering processes are known in the art and detailed in the Examples.

A thin film layer is deposited on a support, the identity and composition of the support depending on the hydrogen sensor configuration. Such supports are known and would be recognized by one of skill in the art. For example, a thin film layer may be deposited for use in situ, such as where the layer is formed on an optic fiber or the like. In another embodiment, a thin film layer is deposited on a support such as a semiconductor wafer and a portion of the film may be subsequently removed to form a pattern on the support. A support further illustratively includes a pyroelectric material, a piezoelectric material, or a thin membrane material as would be found in typical MEMS (microelectromechanical system) devices.

Hydrogen Permeable Layer

An inventive hydrogen sensor includes a hydrogen permeable protective layer deposited on the thin film layer. The hydrogen permeable layer is deposited by a physical vapor deposition process such that a surprisingly high purity layer is formed.

In a preferred embodiment, the hydrogen permeable protective layer inhibits permeation of a gas or gasses other than hydrogen. For example, a preferred hydrogen permeable layer inhibits passage of carbon monoxide, oxygen, hydrogen sulfide, sulfur dioxide or a combination thereof.

In one embodiment, a hydrogen permeable layer is inorganic. Preferably, the inorganic layer includes a compound selected from the group consisting of a metal oxide, a metal nitride, a metal carbide, a metal oxynitride, a semiconductor oxide, a semiconductor nitride, a semiconductor carbide, a semiconductor oxynitride, and combinations thereof.

A hydrogen permeable layer includes a material having a composition represented by the formula: MₐO_{b}N_{c}C_{d} where M is a metal or semiconductor, O is oxygen, N is nitrogen, and C is carbon and a, b, c, and d can each independently range from zero to seven with the proviso that at least two of abcd are non-zero. Where a is greater than one, M may include two or more different metals or semiconductors. Particularly preferred is a hydrogen permeable layer including an oxide of silicon, especially silicon dioxide.

Various assays may be used to ascertain the permeability of a layer to hydrogen. See, for example, Doremus R. H., Diffusion of Reactive Molecules in Solids and Melts. John Wiley & Sons, Inc, 2002; and Beadle W. E., Tsai J. C. C., and Plummer R. D., eds., Quick Reference Manual for Silicon Integrated Circuit Technology. John Wiley & Sons, Inc, 1985.

Optionally, two or more hydrogen permeable layers are included in an inventive sensor, the second hydrogen permeable layer in contact with a first hydrogen permeable layer. Further optionally, the two or more hydrogen permeable layers may have different compositions.

Layer composition may be homogeneous or vary through all or part of the thickness of the layer. For instance, layer composition may vary through the thickness of the layer in a continuous or stepwise manner. Thus, layer composition may vary in a controlled manner as a function of their thickness, the composition controlled, for instance, by varying sputter parameters, target composition, reactive gas composition and the like as will be recognized by one of skill in the art.

A hydrogen permeable layer included in an inventive sensor ranges in thickness between 10-1000 Angstroms in thickness, and more preferably, between 50-400 Angstroms in thickness.

Process for Producing a Hydrogen Permeable Layer on a Substrate

A process is provided for producing a hydrogen permeable layer on a substrate. In a preferred embodiment a hydrogen permeable layer is deposited on a substrate that includes a thin film layer as described herein.

In one embodiment of an inventive sensor, a hydrogen permeable layer is formed by a sputtering process, preferably by a magnetron sputtering process. Further preferred is a sputtering method employs a direct current sputtering source, and/or a pulsed direct current source. General aspects of sputtering processes are known in the art and detailed in the Examples.

A particularly preferred sputtering process for producing a hydrogen permeable layer including an oxide of a metal or semiconductor, is a reactive sputtering process which employs a conductive sputtering target that includes a carbide of the metal or semiconductor enabling the use of a dc power supply. This process includes the step of providing a target including a carbide of the metal or semiconductor. For example, in the case where an oxide of silicon is included in the hydrogen permeable layer, the process includes the step of providing a target containing silicon carbide. Similarly, a hydrogen permeable layer containing an oxide such as GeO₂, Ta₂O₅, TiO₂, HfO₂, WO₃, ZrO₂, Nb₂O₅, V₂O₃, V₂O₄, V₂O₅, Al₂O₃ and CrO₃, may be produced using an appropriate carbide target, i.e. GeC, TaC, TiC, HfC, WC, ZrC, NbC, VC, AlC, or Cr₃C₂. Silicon carbide targets, and targets of alternative composition, are commercially available. For instance a SiC target, Hexoloy SG SiC, is available from Saint-Gobain Advanced Ceramics, Niagara Falls, N.Y.

A further step in an inventive process includes bombarding the target with ions from a reactive plasma sputtering source, such that an oxide of the metal or semiconductor is produced. The reactive plasma preferably includes oxygen.

Another step in an inventive process includes positioning a substrate such that the oxide of the metal or semiconductor is deposited on the substrate, thereby producing the hydrogen permeable layer as described herein containing the oxide of a metal or semiconductor on the substrate.

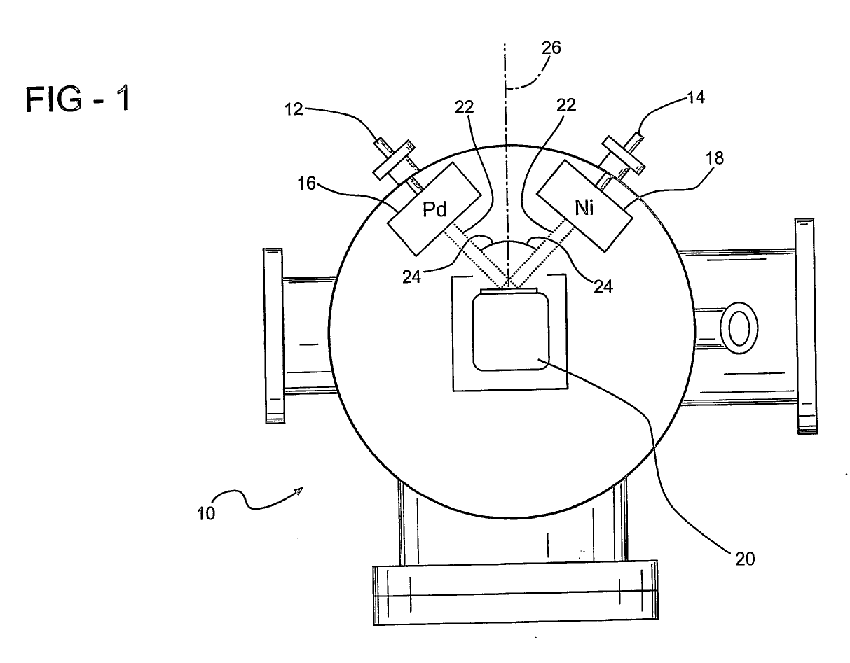

An exemplary system for sputtering formation of a hydrogen permeable layer and/or a thin film layer for inclusion in an inventive sensor is shown generally in FIG. 1 at 10. In this configuration, a direct current source 12 and a pulsed direct current source 14 are shown. Targets 16 and 18 are associated with direct current sources 12 and 14 respectively. A sample holder 20 allows positioning of a substrate on which a thin film layer and/or hydrogen permeable layer is deposited. Distances 22 between the targets 16 and 18 and the sample holder 20 may be adjusted, as can the angles 24 between the targets 16 and 18 and the normal plane 26 of the specimen holder. Targets 16 and 18 may have the same or different composition.

In an optional step, the thin film metal layer is also formed by sputter deposition, preferably magnetron sputtering using a direct current sputtering source, and/or a pulsed direct current source. Optionally, the thin film layer and hydrogen permeable layer or layers are formed sequentially in a sputtering chamber, without breaking vacuum.

### EXAMPLES

### Example 1

Formation of a Thin Film Layer

A combination of evaporation and sputtering was used to deposit a thin metal film. The metal film is patterned by the “lift-off” process. Aluminum is used for contact pads in this case and Pd/Pd—Ni alloys are used for resistor lines. Sputtering is used to deposit Pd and Pd/Ni alloys on a Si₃N₄ substrate. An adhesion layer of chromium, about 200 Angstroms in thickness, is used to improve adhesion of Al and Pd on the nitride surface. Chromium was deposited by e-gun evaporation and the Al contact pads was deposited by evaporation using a thermal source.

An evaporation system (Kurt J. Lesker Co, Clairton, Pa.) with both thermal and e-gun source or the like is used for evaporating chromium for an adhesion layer for contact pads and resistor lines and aluminum—for contact pads. The system is pumped to a base pressure of about 5×10−6 torr by a cryo pump. The pressure during the evaporation process is about 10−5 torr. The deposition rate and film thickness are monitored by a crystal thickness monitor. Pellets of 99.95% pure metal (Al and Cr) are used as the metal source. For contact pad deposition, a 200 Angstrom thick film of Cr is deposited, followed by a 1500 to 2000 Angstrom thick Al film. Both films are deposited without breaking vacuum. Subsequently, the wafer is patterned using a mask to form resistor lines. A 200 Angstrom thick Cr film is deposited on the patterned wafer. The wafer is then cleaved into about 1 inch square pieces (4 dies) for Pd or Pd—Ni alloy film deposition.

Palladium thin films are deposited in a cylindrical vacuum chamber 25 cm in diameter and 20 cm in height with a balanced magnetron sputter gun 2 inches in diameter. The target material used is a 2 inch diameter and ⅛ inch thick body of palladium metal (99.5%). This source could deposit a uniform film over an area of about 1 inch diameter. The target to substrate distance is maintained at 100 mm. The Pd target is oriented at about 45 degrees off the normal to the substrate (see FIG. 1). The chamber is pumped to a base pressure of about 5×10−7 torr by a cryo pump (CTI8 cryo pump). Argon gas is fed into the system through a mass flow controller. The pressure is set by fixing the flow rate and manually controlling the valve used to isolate the cryo pump from the chamber. An Advanced Energy MDX-1K DC power source and an ENI RPG-50 pulsed DC source are used for thin film deposition. The source and the substrate are monitored with an oscilloscope (HP 54603B).

### Example 2

Formation of a Hydrogen Permeable Layer

SiO₂ is deposited by reactive pulsed DC sputtering from an electrically conducting SiC target doped with graphite. The sputter system is the same as used for Pd deposition. Here, the SiC target is located normal to the substrate (see FIG. 1). A 15 percent oxygen and argon gas mixture at 10 mtorr total pressure is used for deposition. The pulsed DC source is operated at 100 W, 680 nm pulse width and 160 kHz frequency. Under these conditions, the carbon from the target is burned by the oxygen ambient resulting in near stoichiometrically pure SiO₂. The quality of the oxide is verified by FTIR and optical spectrometry.

### Example 3

Magnetron Sputtering—Pulsed DC Source

An asymmetric bipolar pulsed DC power supply from ENI (20 W, 145 kHz, 440 ns) is used in conjunction with a magnetron sputter gun to deposit Pd films on a floating (electrically) silicon/silicon nitride substrate. Under these conditions the duty cycle is around 50 percent. The input signal at the magnetron gun and at the substrate are measured by an oscilloscope. This power supply does not supply uniform negative potential to the target (cathode), but a time varying voltage reaching a maximum of about −400 V at 20 W power. In the positive cycle of the pulse, the voltage oscillates before attaining a steady state at around 85 V. The oscillations at the source varied from about 300 V to about −100 V and lasted for about 50 percent of the time period of the positive cycle. During this part of the cycle the plasma potential would increase to just over 85 V. Since the substrate is electrically floating, it follows the plasma potential. The potential of the floating substrate is measured to be around 60 V with respect to the ground potential. In the negative part of the pulse, the anode potential is measured to be slightly negative. This behavior is independent of the target material and has been observed when other target materials like Zn, Ni, SiC, etc have been used. The input pulse shape seems to be solely dependent on the power source and pulse shape. The pulse shape is found to be independent of the pressure, frequency and pulse width.

### Example 4

An alloy film may be deposited by co-sputtering Pd using a DC source and Ni using a pulsed DC source. The alloy composition is determined by the sputter rates of Pd and Ni. The sputter rate is dependent on the input power, among other deposition conditions such as pressure, etc. The sputter rate is directly related to the input power: hence, by altering the power ratio i.e., input power to Pd/input power to Ni, it is possible to change the amount of Ni in the film. In a similar manner, by changing other process variables such as sputtering gas (Xe or Kr), pressure, substrate temperature, or target to substrate distance, both the composition and morphology of the film can be tailored. Thin film properties are verified by x-ray diffraction data, atomic force microscopy, and scanning electron microscopy. The composition of Pd/Ni alloy films is also verified by electron microprobe technique.

Any patents or publications mentioned in this specification are indicative of the levels of those skilled in the art to which the invention pertains. These patents and publications are herein incorporated by reference to the same extent as if each individual publication was specifically and individually indicated to be incorporated by reference. In particular, provisional application U.S. Ser. No. 60/442,397, filed Jan. 23, 2003, is incorporated herein in its entirety.

One skilled in the art will readily appreciate that the present invention is well adapted to carry out the objects and obtain the ends and advantages mentioned, as well as those inherent therein. The present methods, procedures, treatments, molecules, and specific compounds described herein are presently representative of preferred embodiments, are exemplary, and are not intended as limitations on the scope of the invention. Changes therein and other uses will occur to those skilled in the art which are encompassed within the spirit of the invention as defined by the scope of the claims.

We claim:

1. A hydrogen sensor comprising:
a metal film which is capable of altering at least one of its physical parameters when exposed to hydrogen; and
a hydrogen permeable inorganic layer deposited on the metal film, wherein the inorganic layer is deposited by a physical vapor deposition process.

2. The hydrogen sensor of claim 1, wherein the physical vapor deposition process is magnetron sputtering deposition.

3. The hydrogen sensor of claim 2 wherein the magnetron sputtering deposition includes magnetron sputtering using a direct current power source.

4. The hydrogen sensor of claim 3 wherein the direct current power source is a pulsed direct current power source.

5. The hydrogen sensor of claim 1 wherein the metal film comprises a catalytic metal.

6. The hydrogen sensor of claim 1 wherein the metal film comprises palladium.

7. The hydrogen sensor of claim 6 wherein the metal film further comprises nickel.

8. The hydrogen sensor of claim 7 wherein the nickel is present in amounts ranging between 0.1-20% of the total weight of the metal film.

9. The hydrogen sensor of claim 1 wherein the inorganic layer comprises a compound selected from the group consisting of: a metal oxide, a metal nitride, a metal carbide, a metal oxynitride, a semiconductor oxide, a semiconductor nitride, a semiconductor carbide, a semiconductor oxynitride, and combinations thereof.

10. The hydrogen sensor of claim 1 wherein the inorganic layer comprises an oxide of silicon.

11. The hydrogen sensor of claim 10 wherein the oxide of silicon is silicon dioxide.

12. The hydrogen sensor of claim 1 wherein the inorganic layer ranges between 10-1000 Angstroms in thickness.

13. The hydrogen sensor of claim 1 wherein the inorganic layer ranges between 50-400 Angstroms in thickness.

14. A process for producing a hydrogen permeable layer on a substrate, the layer comprising an oxide of a metal or semiconductor, the process comprising the steps of:
providing a target, the target comprising a carbide of the metal or semiconductor;
bombarding the target with ions created by a reactive plasma sputtering source such that an oxide of the metal or semiconductor is produced; and
positioning a substrate such that the oxide of the metal or semiconductor is deposited on the substrate, thereby producing the layer comprising the oxide of a metal or semiconductor on the substrate.

15. The process of claim 14 further including the step of producing a substrate.

16. The process of claim 15 wherein the substrate is a thin metal film comprising a catalytic metal.

17. The process of claim 16 wherein the catalytic metal is selected from the group consisting of: Pd, Pt, Ni, Au, Ag and an alloy thereof.

18. The process of claim 16 wherein the thin metal film is deposited on a support by a sputtering process.

19. The process of claim 14 wherein the semiconductor is silicon.

20. The process of claim 14 wherein the target comprises silicon carbide.

21. The process of claim 14 wherein the reactive plasma comprises oxygen.

22. The process of claim 14 wherein the metal comprises a transition metal.

23. The process of claim 14 wherein the sputtering source is a direct current magnetron sputtering source.

24. The process of claim 23 wherein the direct current magnetron sputtering source is a pulsed direct current magnetron sputtering source.

25. A hydrogen sensor comprising:
a thin film comprising palladium, the film capable of altering at least one of its physical parameters when exposed to hydrogen; and
a hydrogen permeable layer comprising an oxide of silicon deposited on the thin film, wherein the hydrogen permeable layer is deposited by a pulsed direct current magnetron sputtering deposition process.

26. The hydrogen sensor of claim 25 wherein the thin film further comprises nickel.

27. The hydrogen sensor of claim 25 wherein the pulsed direct current magnetron sputtering deposition process comprises the step of providing a target, the target comprising silicon carbide.

28. The hydrogen sensor of claim 25 wherein the thin film is formed by a direct current magnetron sputtering deposition process.

29. A hydrogen sensor comprising:
a metal film comprising palladium, the film capable of altering at least one of its physical parameters when exposed to hydrogen; and
a hydrogen permeable inorganic layer comprising silicon dioxide deposited on the metal film, wherein the hydrogen permeable inorganic layer is deposited by a pulsed direct current magnetron sputtering deposition process and wherein the hydrogen permeable inorganic layer ranges between 10-1000 Angstroms in thickness.

30. The hydrogen sensor of claim 29 wherein the metal film further comprises nickel.

31. The hydrogen sensor of claim 30 wherein the nickel is present in an amount in the range between 0.1-20% of the total weight of the metal film.

32. The hydrogen sensor of claim 30 wherein the nickel is present in an amount in the range between 0.5-10% of the total weight of the metal film.

33. The hydrogen sensor of claim 29 wherein the thin film is formed by a direct current magnetron sputtering deposition process.
